(19) United States
(12) Patent Application Publication
(10) Pub. No.: US 2025/0358967 A1
(43) Pub. Date: Nov. 20, 2025

(54) HEAT CONDUCTION PLATE, HEAT DISSIPATION APPARATUS, AND ELECTRONIC DEVICE

(71) Applicant: ZTE CORPORATION, Shenzhen (CN)

(72) Inventors: Kaiwen DUAN, Shenzhen (CN); Zhidong NIE, Shenzhen (CN); Xin LIU, Shenzhen (CN); Yan WANG, Shenzhen (CN); Fan LIU, Shenzhen (CN); Shuai LI, Shenzhen (CN)

(21) Appl. No.: 18/868,443

(22) PCT Filed: Jan. 28, 2023
(86) PCT No.: PCT/CN2023/073625

§ 371 Date: Nov. 22, 2024

(30) Foreign Application Priority Data
Jun. 29, 2022 (CN) 202210747500.6

(51) Int. Cl. H05K 7/20

(52) U.S. Cl. CPC H05K 7/20327

(57) ABSTRACT

A heat conducting plate, a heat dissipation apparatus, and an electronic device are disclosed. The heat conducting plate may include: a heat conducting plate body, and a first heat dissipation zone, a second heat dissipation zone, and a third heat dissipation zone which are arranged on the heat conducting plate body.

### CROSS-REFERENCE TO RELATED APPLICATION

This application is a national stage filing under 35 U.S.C. § 371 of international application number PCT/CN2023/073625, filed Jan. 28, 2023, which claims priority to Chinese patent application No. 202210747500.6 filed Jun. 29, 2022. The contents of these applications are incorporated herein by reference in their entirety.

### TECHNICAL FIELD

Embodiments of the present disclosure relate to the technical field of heat dissipation, and more particularly, to a heat conducting plate, a heat dissipation apparatus, and an electronic device.

### BACKGROUND

As electronic devices evolve towards higher power, greater integration, and lighter weight, their heat generation density increases, leading to greater demands for efficient heat dissipation. In related heat dissipation technologies, a heat conducting plate using a two-phase heat dissipation method is adopted.

However, existing heat conducting plates using two-phase heat dissipation technologies have low two-phase circulation efficiency, and heat dissipation apparatuses and electronic devices using the existing heat conducting plates have an unsatisfactory heat dissipation effect.

Therefore, there is an urgent need for a heat conducting plate, a heat dissipation apparatus, and an electronic device to address the problems of low two-phase circulation efficiency of heat conducting plates and an unsatisfactory heat dissipation effect of heat dissipation apparatuses and electronic devices.

### SUMMARY

Embodiments of the present disclosure provide a heat conducting plate, a heat dissipation apparatus, and an electronic device.

In accordance with a first aspect of the present disclosure, an embodiment provides a heat conducting plate, including: a heat conducting plate body, and a first heat dissipation zone, a second heat dissipation zone, and a third heat dissipation zone which are arranged on the heat conducting plate body. The first heat dissipation zone is arranged adjacent to a first side of the heat conducting plate body. The first side of the heat conducting plate body is configured as a heat input end. The second heat dissipation zone is arranged adjacent to the first heat dissipation zone, and the second heat dissipation zone is provided with a second heat dissipation channel. The third heat dissipation zone is arranged adjacent to the first heat dissipation zone and the second heat dissipation zone, and the third heat dissipation zone is provided with a third heat dissipation channel. The second heat dissipation channel includes at least a mesh-shaped channel. The third heat dissipation channel includes at least a strip-shaped channel. The second heat dissipation channel is communicated with the third heat dissipation channel.

In accordance with a second aspect of the present disclosure, an embodiment provides a heat dissipation apparatus, including a base and the heat conducting plate according to the first aspect. The base is connected to the heat conducting plate.

In accordance with a third aspect of the present disclosure, an embodiment provides an electronic device, including the heat conducting plate according to the first aspect, or including the heat dissipation apparatus according to the second aspect.

### BRIEF DESCRIPTION OF DRAWINGS

FIG. 1 is a schematic structural sectional diagram of a heat conducting plate according to an embodiment of the present disclosure;

FIG. 2 is a schematic structural sectional diagram of a heat conducting plate according to an embodiment of the present disclosure;

FIG. 3 is a schematic structural sectional diagram of a heat conducting plate according to an embodiment of the present disclosure;

FIG. 4 is a schematic structural sectional diagram of a heat conducting plate according to an embodiment of the present disclosure;

FIG. 5 is a schematic structural sectional diagram of a heat conducting plate according to an embodiment of the present disclosure;

FIG. 6 is a schematic structural sectional diagram of a heat conducting plate according to an embodiment of the present disclosure;

FIG. 7a is a schematic structural sectional diagram of a heat conducting plate according to an embodiment of the present disclosure;

FIG. 7b is a schematic structural sectional diagram of a heat conducting plate according to an embodiment of the present disclosure; and

FIG. 7c is a schematic structural sectional diagram of a heat conducting plate according to an embodiment of the present disclosure.

### REFERENCE NUMERALS

1: heat conducting plate;
10: first heat dissipation zone; 20: second heat dissipation zone; 30: third heat dissipation zone; 40: coupling zone; and 50: collecting groove;
101: first heat dissipation channel; 201: second heat dissipation channel; 202: first closed unit; 301: third heat dissipation channel; 302: second closed unit; and 401: coupling zone channel; and
2011: diffusion pipe; 3011: guide pipe; and 3012: communicating pipe.

### DETAILED DESCRIPTION

To make the objectives, technical schemes, and advantages of the present disclosure clearer and more comprehensible, the present disclosure is further described below in detail in conjunction with the accompanying drawings and embodiments. It should be understood that the specific embodiments described herein are merely used to illustrate the present disclosure and are not intended to limit the present disclosure.

In the descriptions of the embodiments of the present disclosure, the terms such as “first”, “second” and the like (if any) used herein are merely used for distinguishing technical features, and are not intended to indicate or imply relative importance, or implicitly point out the number of the indicated technical features, or implicitly point out a precedence order of the indicated technical features.

It should be understood that, terms such as “upper”, “lower”, “front”, “rear”, “left”, “right” and the like should be construed to refer to the orientation or positional relationships as then described or as shown in the drawings under discussion. These relative terms are for convenience of description and do not require that the apparatus or elements of the present disclosure have a particular orientation or be constructed or operated in a particular orientation. Unless otherwise explicitly limited, terms such as “arrange”, “install”, “connect” and the like should be understood in a broad sense. Those having ordinary skills in the art can properly determine specific meanings of the terms in the embodiments of the present disclosure based on specific contents of the technical schemes.

Reference throughout this description to “an embodiment”, “some embodiments”, “an example embodiment”, “a specific example”, or “some examples” means that a particular feature, structure, material, or characteristic described in connection with the embodiment or example is included in at least one embodiment or example of the present disclosure. Thus, the appearances of the phrases throughout this description are not necessarily referring to the same embodiment or example of the present disclosure. Furthermore, the particular features, structures, materials, or characteristics may be combined in any suitable manner in one or more embodiments or examples.

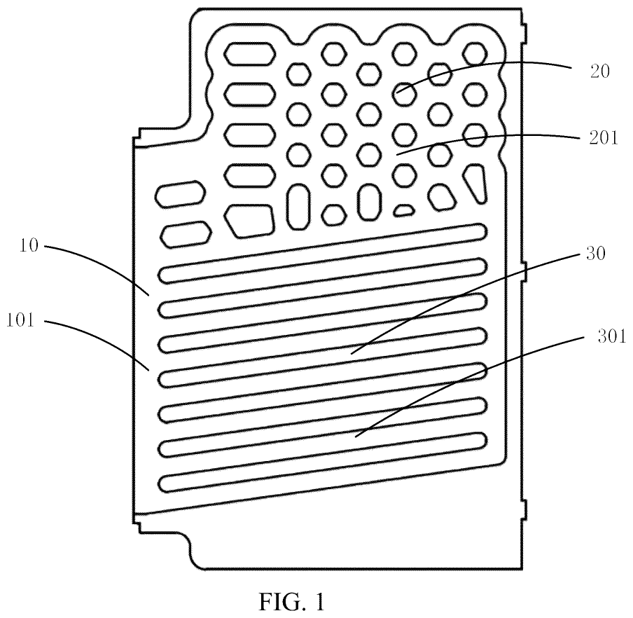

With reference to FIG. 1, an embodiment of the present disclosure provides a heat conducting plate 1, including: a heat conducting plate body, and a first heat dissipation zone 10, a second heat dissipation zone 20, and a third heat dissipation zone 30 which are arranged on the heat conducting plate body. The first heat dissipation zone 10 is arranged adjacent to a first side of the heat conducting plate body. The first side of the heat conducting plate body is configured as a heat input end. The second heat dissipation zone 20 is arranged adjacent to the first heat dissipation zone 10, and the second heat dissipation zone 20 is provided with a second heat dissipation channel 201. The third heat dissipation zone 30 is arranged adjacent to the first heat dissipation zone 10 and the second heat dissipation zone 20, and the third heat dissipation zone 30 is provided with a third heat dissipation channel 301. The second heat dissipation channel 201 is communicated with the third heat dissipation channel 301.

The heat conducting plate 1 further includes a heat-conducting working medium configured to flow in the second heat dissipation channel 201 and the third heat dissipation channel 301. The second heat dissipation channel 201 is configured to liquefy at least part of the heat-conducting working medium. The liquefied heat-conducting working medium in the second heat dissipation channel 201 flows to the third heat dissipation channel 301 through the second heat dissipation channel 201. The second heat dissipation channel 201 has a different structure from the third heat dissipation channel 301.

In some implementations, the second heat dissipation channel 201 includes at least a mesh-shaped channel. The mesh-shaped channel is a non-directional array channel that helps diffuse a vapor-state heat-conducting working medium. The vapor-state heat-conducting working medium flows in a plurality of directions in the second heat dissipation channel 201 to achieve a higher flow efficiency and a larger contact area to accelerate condensation of the heat-conducting working medium. The flow directions of the vapor-state heat-conducting working medium in the second heat dissipation channel 201 are affected at least by a local temperature difference, an air density difference, an air pressure difference, a channel form, and the like inside the second heat dissipation channel 201. It can be understood that the second heat dissipation channel 201 may be a non-linear channel, i.e., an inlet and an outlet of the non-linear channel are not in one-to-one correspondence. For example, the second heat dissipation channel 201 may be in a shape similar to a grid or a honeycomb.

The third heat dissipation channel 301 includes at least a strip-shaped channel. The strip-shaped channel is a directional guide channel that helps guide a liquid-state heat-conducting working medium. The liquid-state heat-conducting working medium has a clear flow direction in the third heat dissipation channel 301 to achieve a directional flow of the heat-conducting working medium in the third heat dissipation channel 301 to improve return efficiency. The liquid-state heat-conducting working medium flows in a relatively specific direction in the third heat dissipation channel 301, i.e., at least flows along the interior of the third heat dissipation channel 301 under driving of self-gravity of the liquid-state heat-conducting working medium. It can be understood that the third heat dissipation channel 301 may be a linear channel. The linear channel has an inlet and outlet clearly in one-to-one correspondence.

Further, due to a density difference between the vapor-state heat-conducting working medium and the liquid-state heat-conducting working medium, as affected by a pressure difference and thermal buoyancy, the light-density vapor-state heat-conducting working medium tends to quickly gather at an upper part of the heat conducting plate 1. In this way, the heat-conducting working medium in the third heat dissipation channel 301 has fewer and independent flow paths, a unitary discharge path, and larger flow resistance, while the heat-conducting working medium in the second heat dissipation channel 201 has more and intersecting flow paths, so that diffusion paths of the vapor-state heat-conducting working medium can be significantly increased to reduce diffusion resistance. In addition, it is more difficult for the vapor-state heat-conducting working medium to climb upward in the third heat dissipation channel 301 than in the second heat dissipation channel 201, and the second heat dissipation channel 201 provides a large number of upward channels and lateral diffusion channels for the vapor-state heat-conducting working medium, which helps the vapor-state heat-conducting working medium to gather upwards and diffuse in a plane direction, thereby reducing upward resistance and diffusion resistance of vapor and improving diffusion efficiency. Further, it is easier for the second heat dissipation channel 201 to increase density than the third heat dissipation channel 301, so that a contact area between the second heat dissipation channel 201 and the heat-conducting working medium can be significantly increased, and the vapor-state heat-conducting working medium can obtain a greater condensation area for exothermic condensation, thereby improving condensation efficiency.

It can be understood that the heat-conducting working medium enters the second heat dissipation channel 201 mainly in a vapor form, and enters the third heat dissipation channel 301 mainly in a liquid form. Under a joint action of diffusion and condensation functions of the second heat dissipation channel 201 and guide and return functions of the third heat dissipation channel 301, a heat conduction cycle of the heat-conducting working medium is realized, thereby improving two-phase circulation efficiency of the heat-conducting working medium.

In some implementations, the first heat dissipation zone 10 is provided with a first heat dissipation channel 101. The first heat dissipation channel 101 is communicated with the third heat dissipation channel 301, to receive the heat-conducting working medium from the third heat dissipation channel 301. The first heat dissipation channel 101 is arranged to provide a space for the heat-conducting working medium to transform from the liquid state to the vapor state. Therefore, a phase change occurring in the first heat dissipation channel 101 mainly includes the transformation from the liquid state to the vapor state, and because this process involves mainly heat absorption, the first heat dissipation zone 10 is arranged close to the heat input end of the heat conducting plate 1, and the first heat dissipation channel 101 is arranged on a side of the third heat dissipation channel 301 close to the heat input end. It can be understood that, to enable the vapor-state heat-conducting working medium to enter the second heat dissipation channel 201 to achieve a satisfactory circulation effect, the first heat dissipation channel 101 is further communicated with the second heat dissipation channel 201. The first heat dissipation channel 101 is configured to vaporize the heat-conducting working medium. The vaporized heat-conducting working medium flows to the second heat dissipation channel 201 through the first heat dissipation channel 101. Therefore, a communication status in this case is that the second heat dissipation channel 201 is communicated with the third heat dissipation channel 301, the third heat dissipation channel 301 is communicated with the first heat dissipation channel 101, and the first heat dissipation channel 101 is communicated with the second heat dissipation channel 201. A phase change of the heat-conducting working medium in the second heat dissipation channel 201 is liquefaction, the heat-conducting working medium in the third heat dissipation channel 301 is mainly a liquefied heat-conducting working medium, and is guided into the first heat dissipation channel 101, and the liquefied heat-conducting working medium in the first heat dissipation channel 101 is mainly vaporized.

It can be understood that the first heat dissipation channel 101 may be a hollow pipe structure, which can provide a space for the vapor-state heat-conducting working medium to flow freely. Alternatively, the first heat dissipation channel 101 may be a mesh pipe structure that is not completely hollow inside. The mesh pipe structure provides a larger contact area between the liquid-state heat-conducting working medium and the first heat dissipation channel 101, which helps accelerate evaporation of the liquid-state heat-conducting working medium.

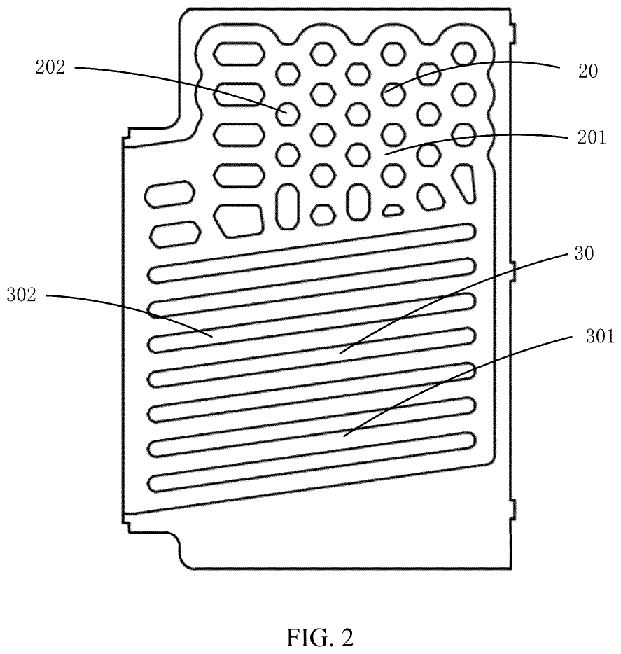

With reference to FIG. 2, the second heat dissipation zone 20 includes a plurality of first closed units 202. In some implementations, the plurality of first closed units 202 form the second heat dissipation zone 20 together with the second heat dissipation channel 201 through at least one of offset, arraying, or outward expansion. Shapes of the first closed units 202 include, but not limited to, one or a combination of at least two of a circle, an ellipse, a triangle, a quadrilateral, a pentagon, a hexagon, or other polygons. The first closed units 202 of a single shape and size or a plurality of shapes and sizes are arranged to form a regular or irregular structure. It can be understood that the first closed units 202 include at least one shape or size. The second heat dissipation channel 201 is arranged at least partly around the first closed units 202, and the first closed units 202 are arranged at multi points. This can increase the flow paths and a condensation area of the vapor-state heat-conducting working medium in the second heat dissipation channel 201, and reduce diffusion resistance of the vapor-state heat-conducting working medium.

The third heat dissipation zone 30 includes a plurality of second closed units 302. In some implementations, the plurality of second closed units 302 form the third heat dissipation zone 30 together with the third heat dissipation channel 301 through at least one of offset, arraying, and outward expansion. Shapes of the second closed unit 302 include, but not limited to, one or a combination of at least two of a quadrilateral, an oval, or other polygons. In some implementations, the second closed units 302 are oval. The second closed units 302 of a single shape and size or a plurality of shapes and sizes are arranged to form a regular or irregular structure. The second closed units 302 include at least one shape or size. The third heat dissipation channel 301 is arranged at least partly around the second closed units 302.

In some implementations, the first closed unit 202 and the second closed unit 302 have different shapes, or the first closed unit 202 and the second closed unit 302 have different sizes, which includes at least a case that the first closed unit 202 and the second closed unit 302 have different shapes and sizes, and a case that the first closed unit 202 and the second closed unit 302 have the same shape but different sizes.

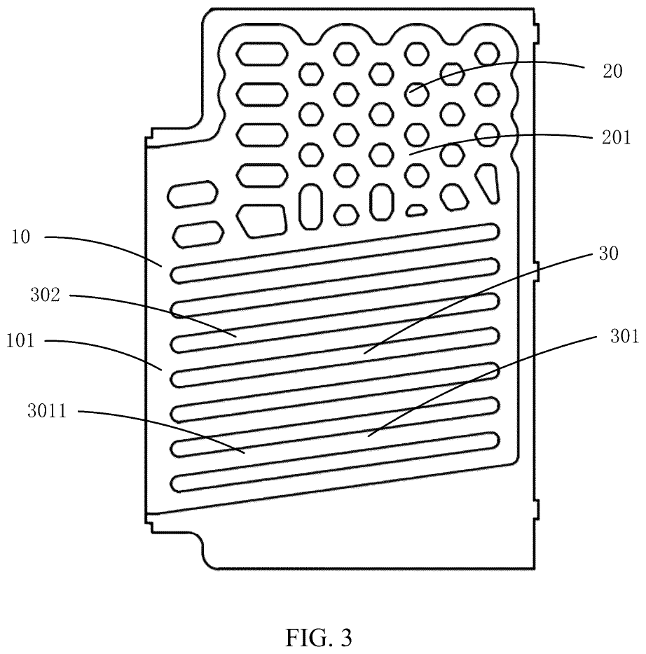

With reference to FIG. 3, the third heat dissipation channel 301 includes a plurality of guide pipes 3011 which are spaced apart. In some implementations, the second closed unit 302 is arranged between adjacent guide pipes 3011 to achieve spacing of the guide pipes 3011.

In some implementations, the guide pipe 3011 has an inlet arranged close to the second heat dissipation zone 20 and an outlet arranged close to the first heat dissipation zone 10, such that the liquid-state heat-conducting working medium flows by self-gravity in a direction from the inlet to the outlet close to the heat input end. It can be understood that when the heat conducting plate 1 is in a working state, the outlet is at a lower position in a direction of gravity relative to the inlet, to help the liquid-state heat-conducting working medium to flow. In some implementations, an end of the guide pipe 3011 close to the second heat dissipation zone 20 has a greater diameter than an end of the guide pipe 3011 close to the first heat dissipation zone 10. In other words, the inlet has a greater diameter than the outlet, which increases flow resistance of the vapor-state heat-conducting working medium in the guide pipe 3011, such that the vapor-state heat-conducting working medium in the first heat dissipation channel 101 tends to diffuse from an upper part to the second heat dissipation channel 201 instead of entering the third heat dissipation channel 301 from a lower part of the first heat dissipation channel 101 through the small-diameter guide pipe 3011, thereby facilitating two-phase directional circulation. In some implementations, a diameter of the guide pipe 3011 from the inlet to the outlet is set to gradually decreasing, to facilitate drainage of the liquid-state heat-conducting working medium inside, and increase flow resistance of the vapor-state heat-conducting working medium.

In some implementations, at an end of the third heat dissipation channel 301 close to the heat input end, the guide pipes 3011 are arranged spaced apart along a dripping direction under gravity of the liquid-state heat-conducting working medium for liquid replenishment to different parts of a heat source in the direction of gravity, to improve balance of heat absorption from the heat source. In some implementations, the liquid-state heat-conducting working medium can fully flush and soak the end of the near-heat source third heat dissipation channel 301 close to the heat input end or the first heat dissipation channel 101 from top to bottom along the direction of gravity, which helps resolve a problem of dry burning of an upper part of the third heat dissipation channel 301 near the heat source or an upper part of the first heat dissipation channel 101 due to lack of liquid.

In some implementations, an angle between the end of the guide pipe 3011 close to the first heat dissipation zone 10 and a first direction is less than 45 degrees. In an implementation, the first direction refers to a direction perpendicular to a length of the first heat dissipation channel 101 in a plane where the guide pipe 3011 is located, and is usually a horizontal direction perpendicular to the direction of gravity in a use state. Such an arrangement helps lead out more guide pipes 3011 within a limited area, thereby increasing pipe density and distributing the heat-conducting working medium more evenly.

In some implementations, the plurality of guide pipes 3011 have the same length. With the same length, flow time of the liquid-state heat-conducting working medium in different guide pipes 3011 tends to be the same, such that liquid replenishment efficiency of different guide pipes 3011 is similar.

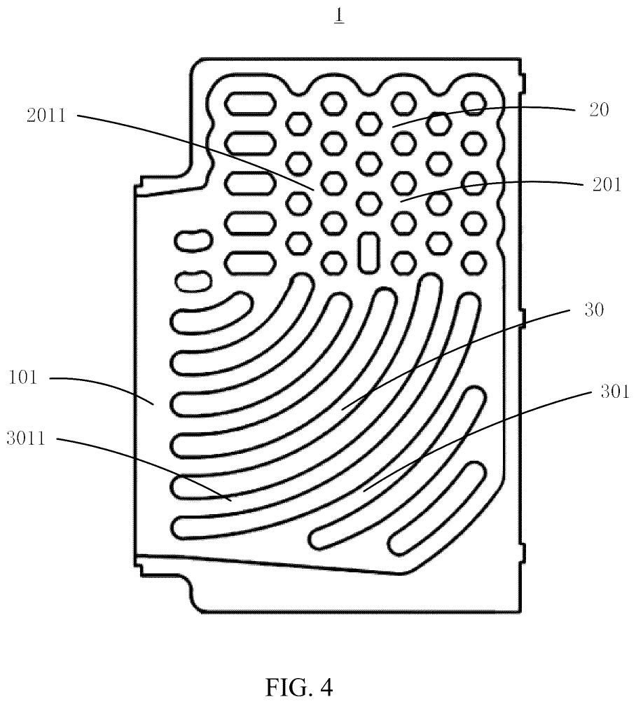

In other implementations, with reference to FIG. 4, at least two guide pipes 3011 have different lengths. The guide pipes 3011 of different lengths shorten flow paths of the liquid-state heat-conducting working medium and reduce flow time, such that the liquid-state heat-conducting working medium reaches the heat input end faster. Because the heat input end usually extends a certain distance in a certain direction, heat distribution is uneven or different parts need to dissipate different amounts of heat. Therefore, guide pipes 3011 of different lengths may be arranged for different parts of the third heat dissipation channel 301 close to the heat input end, to achieve different liquid replenishment efficiency and improve heat dissipation efficiency.

In an implementation, lengths of at least some of adjacent guide pipes 3011 increase gradually. It can be understood that, in two adjacent guide pipes 3011, there is a short guide pipe 3011 and a long guide pipe 3011, and another guide pipe 3011 adjacent to the long guide pipe 3011 is a longer guide pipe 3011. Therefore, lengths of the guide pipes 3011 arranged in this implementation increase gradually, where part of the third heat dissipation channel 301 is in a radially outward expansion structure. In this implementation of the third heat dissipation channel 301, the guide pipes 3011 are led out from the first heat dissipation channel 101, extend to a lower end of the second heat dissipation channel 201, and form direct communication. Further, the liquid-state heat-conducting working medium formed in the second heat dissipation zone 20 may be directly distributed to the guide pipes 3011 by the second heat dissipation channel 201, and finally is directionally guided to different height directions of the first heat dissipation channel 101 for liquid replenishment. It can be understood that the liquid-state working medium distributed from the second heat dissipation zone 20 to the channels in the third heat dissipation zone 30 is more even, and has a higher directional circulation fluidity.

It can be understood that the second heat dissipation channel 201 includes a diffusion pipe 2011. The diffusion pipe 2011 is arranged around the first closed units, and the vapor-state heat-conducting working medium flows and diffuses in the diffusion pipe 2011.

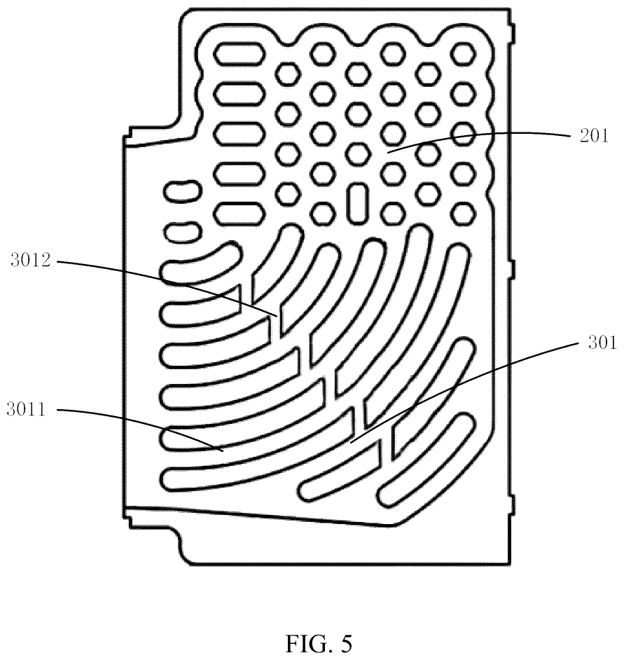

With reference to FIG. 5, in some implementations, the third heat dissipation zone 30 is provided with a communicating pipe 3012. The communicating pipe 3012 connects adjacent guide pipes 3011. The guide pipes 3011 are first connected through the communicating pipe 3012 and then communicated with the second heat dissipation channel 201. The communicating pipe 3012 is arranged penetrating the third heat dissipation channel 301. The communicating pipe 3012 connects two adjacent guide pipes 3011, such that the liquid-state heat-conducting working medium can flow from one guide pipe 3011 to another guide pipe 3011 through the communicating pipe 3012. Therefore, the communicating pipe 3012 can adjust the flow rate of the liquid-state heat-conducting working medium in different guide pipes 3011, to effectively dissipate heat for different heat source conditions.

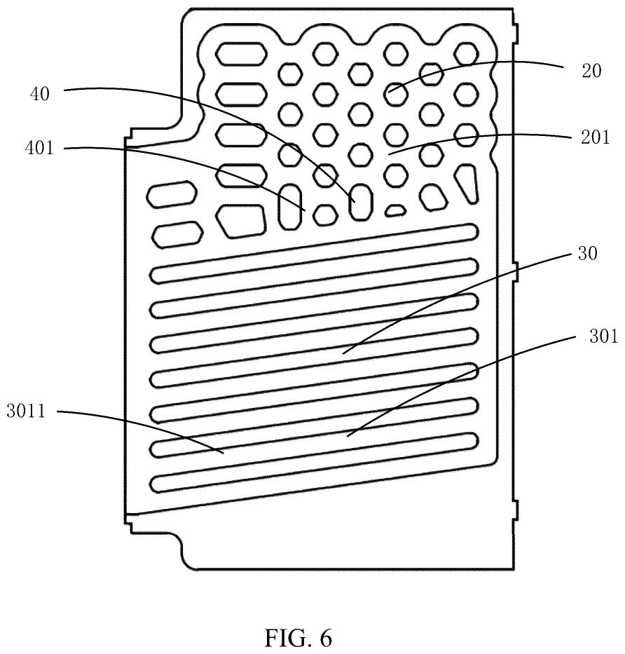

With reference to FIG. 6, in some implementations, a coupling zone 40 is arranged between the second heat dissipation zone 20 and the third heat dissipation zone 30. The second heat dissipation channel 201 is communicated with the third heat dissipation channel 301 by means of the coupling zone 40. A coupling zone channel 401 is a transitional channel form between the second heat dissipation channel 201 and the third heat dissipation channel 301, which can completely separate the second heat dissipation channel 201 from the third heat dissipation channel 301, or partly separate the second heat dissipation channel 201 from the third heat dissipation channel 301.

In some implementations, a boundary of the coupling zone channel 401 defines mainly a linear strip-shaped channel, which is adapted to be locally coupled to a contact part of the second heat dissipation channel 201, to implement transitional communication. In addition, a satisfactory guide effect of the linear strip-shaped channel can be well matched with the third heat dissipation channel 301 to maintain a linear guide effect of the third heat dissipation channel 301 to a greater extent, thereby improving directional liquid return efficiency.

In some implementations, the coupling zone channel 401 is mainly configured for flow distribution rather than guiding. In this case, the coupling zone channel 401 is mainly in a mesh-shaped channel form instead of a linear strip-shaped channel with a clear path. After the vapor-state heat-conducting working medium is liquefied in the second heat dissipation channel 201, a mesh-shaped channel is specifically arranged according to different flow rates after liquefaction in different parts, such that the liquid-state heat-conducting working medium can be evenly distributed when flowing through the coupling zone 40 and flow into the guide pipes 3011 in the third heat dissipation channel 301, to improve liquid replenishment efficiency of the third heat dissipation channel 301.

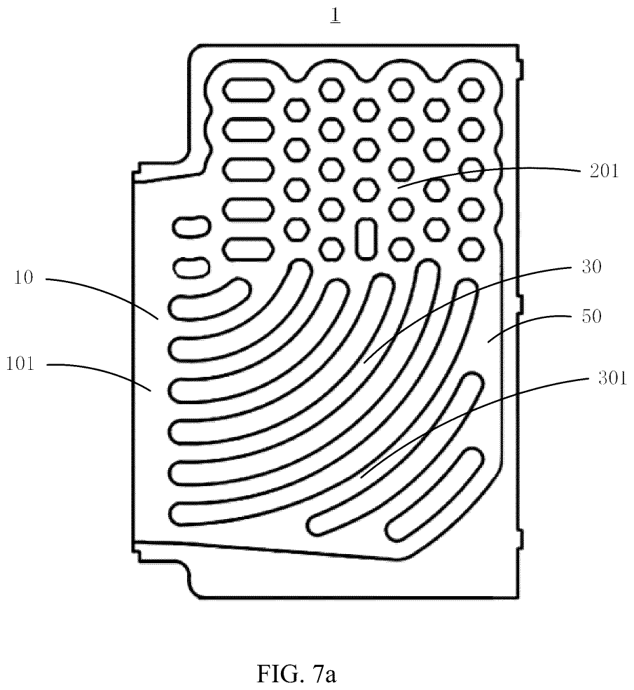

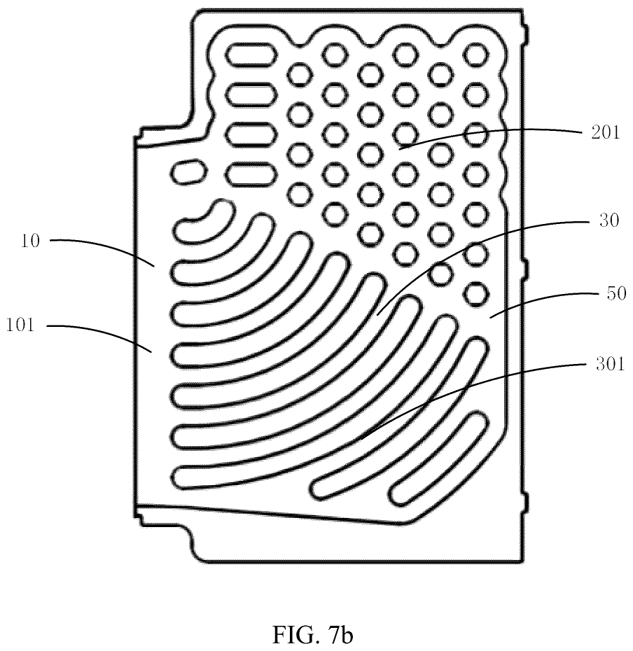

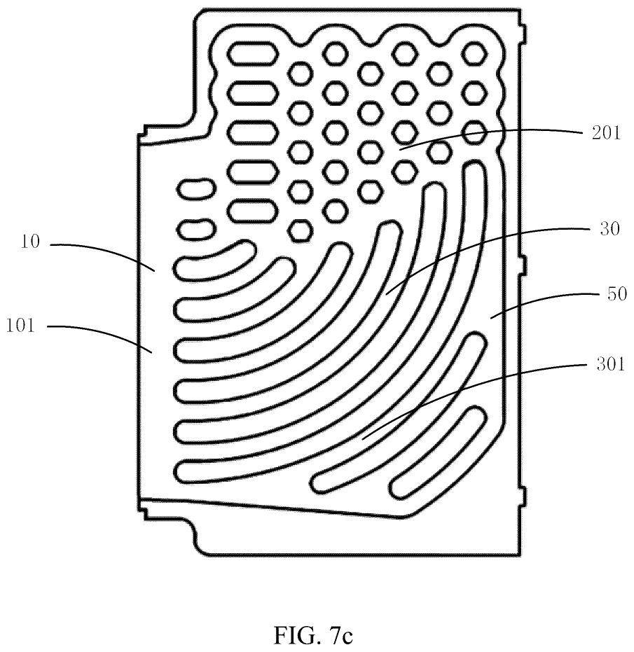

With reference to FIG. 7a, FIG. 7b, and FIG. 7c together, a part where the second heat dissipation channel 201 is adjacent to the third heat dissipation channel 301 may be provided with different structures according to different heat source conditions, including at least one of the following three manners: shifting in a direction from a position of the third heat dissipation channel 301 towards the first heat dissipation channel 101, shifting in a direction from a position of the second heat dissipation channel 201 towards the first heat dissipation channel 101, and not shifting. When the adjacent part is set to shifting in the direction from the position of the third heat dissipation channel 301 towards the first heat dissipation channel 101, the second heat dissipation channel 201 has a larger condensation area than in a not shifting case, thereby improving condensation efficiency. When the adjacent part is set to shifting in the direction from the position of the second heat dissipation channel 201 towards the first heat dissipation channel 101, the liquid-state heat-conducting working medium can enter the third heat dissipation channel 301 and return earlier when condensation efficiency is met.

In an implementation, the heat conducting plate 1 is provided with a collecting groove 50 on a side of the third heat dissipation channel 301 near the first heat dissipation zone 10. The collecting groove 50 is communicated with both the second heat dissipation channel 201 and the third heat dissipation channel 301. It can be understood that the vapor-state heat-conducting working medium flows from the first heat dissipation channel 101 to the second heat dissipation channel 201 mainly through the collecting groove 50.

In an implementation, a small amount of the vapor-state heat-conducting working medium in the first heat dissipation channel 101 may enter the third heat dissipation channel 301, or part of the liquid-state working medium inside the third heat dissipation channel 301 may vaporize. In this case, the vapor-state heat-conducting working medium in the third heat dissipation channel 301 may flow through the third heat dissipation channel 301 to the collecting groove 50 on the side of the third heat dissipation zone 30 away from the first heat dissipation zone 10 to be collected, and then flow to the second heat dissipation channel 201 communicated with the collecting groove 50. In addition, the collecting groove 50 herein further functions to help the second heat dissipation channel 201 to transport the liquid-state heat-conducting working medium to the third heat dissipation channel 301.

An embodiment of the present disclosure provides a heat dissipation apparatus. The heat dissipation apparatus selectively uses the structure of the heat conducting plate 1, and the heat dissipation apparatus includes, but not limited to, heat dissipation apparatuses used in electronic devices such as an Active Antenna Unit (AAU), a Radio Remote Unit (RRU), a charging pile device, and a lighting device. In an implementation, the heat dissipation apparatus includes a base connected to the heat conducting plate 1. When an inner cavity of the base is communicated with the heat conducting plate 1, the heat conducting plate 1 is provided with an open nozzle, that is, the heat input end of the heat conducting plate 1 is provided with an open nozzle, and the inner cavity of the base is communicated with the heat conducting plate 1 through the open nozzle. Therefore, the inner cavity of the base may be communicated with the first heat dissipation channel 101 of the heat conducting plate 1 through the open nozzle, and a heat-conducting working medium can flow into and out of the inner cavity of the base through the open nozzle, to significantly improve overall two-phase temperature equalization and heat dissipation efficiency of the heat dissipation apparatus. In another implementation, the inner cavity of the base is not communicated with the heat conducting plate 1, and the heat conducting plate 1 has a closed nozzle, that is, the heat input end of the heat conducting plate 1 has a closed nozzle, and the heat-conducting working medium flows only inside the heat conducting plate 1. This simplifies the connection between the heat conducting plate 1 and the base, and reduces a process/production failure rate and leakage rate.

In some implementations, with the adoption of the heat conducting plate 1, the heat dissipation apparatus has beneficial effects of corresponding structures of the heat conducting plate 1, including at least as follows: A vapor-state heat-conducting working medium flows in a plurality of directions in the second heat dissipation channel 201 to achieve a higher flow efficiency and a larger contact area to accelerate condensation of the heat-conducting working medium. A liquid-state heat-conducting working medium has a clear flow direction in the third heat dissipation channel 301 for directional flow of the heat-conducting working medium in the third heat dissipation channel 301 to improve return efficiency. Under a joint action of a diffusion function of the second heat dissipation channel 201 and a guide function of the third heat dissipation channel 301, a heat conduction cycle of the heat-conducting working medium is realized, thereby improving two-phase circulation efficiency of the heat-conducting working medium.

An embodiment of the present disclosure provides an electronic device. The electronic device selectively uses the structure of the heat conducting plate 1, or selectively uses the structure of the heat dissipation apparatus. The electronic device includes, but not limited to, base station devices such as an AAU or an RRU, electromechanical devices such as a charging pile device or a lighting device, or other communication electronic devices such as a mobile phone or a computer. The electronic device dissipates heat by utilizing the heat conducting plate 1 or the heat dissipation apparatus to reduce an operating temperature. Further, when using the structure of the heat conducting plate 1 or the heat dissipation apparatus, the electronic device has beneficial effects of corresponding structures of the heat conducting plate 1, including at least as follows: A vapor-state heat-conducting working medium flows in a plurality of directions in the second heat dissipation channel 201 to achieve a higher flow efficiency and a larger contact area to accelerate condensation of the heat-conducting working medium. A liquid-state heat-conducting working medium has a clear flow direction in the third heat dissipation channel 301 for directional flow of the heat-conducting working medium in the third heat dissipation channel 301 to improve return efficiency. Under a joint action of a diffusion function of the second heat dissipation channel 201 and a guide function of the third heat dissipation channel 301, a heat conduction cycle of the heat-conducting working medium is realized, thereby improving two-phase circulation efficiency of the heat-conducting working medium.

In the heat conducting plate according to the embodiments of the present disclosure, a first heat dissipation zone, a second heat dissipation zone, and a third heat dissipation zone are arranged on a heat conducting plate body, and different heat dissipation zones are mainly responsible for different phase changes or specific functions, such that the phase changes occur cyclically and orderly. In addition, the arrangement of different zones makes a heat conduction path in the heat conducting plate clear and improves heat conduction efficiency. The second heat dissipation zone is provided with a second heat dissipation channel, the third heat dissipation zone is provided with a third heat dissipation channel, the second heat dissipation channel includes at least a mesh-shaped channel, the third heat dissipation channel includes at least a strip-shaped channel, and the second heat dissipation channel is communicated with the third heat dissipation channel. The mesh-shaped channel is a non-directional array channel that helps diffuse a vapor-state heat-conducting working medium. The vapor-state heat-conducting working medium flows in a plurality of directions in the second heat dissipation channel to achieve a higher flow efficiency and a larger contact area to accelerate condensation of the heat-conducting working medium. The strip-shaped channel is a directional guide channel that helps guide flow of a liquid-state heat-conducting working medium. The liquid-state heat-conducting working medium has a clear flow direction in the third heat dissipation channel for directional flow of the heat-conducting working medium in the third heat dissipation channel to improve return efficiency. Under a joint action of a diffusion function of the second heat dissipation channel and a guide function of the third heat dissipation channel, a heat conduction cycle of the heat-conducting working medium is realized, thereby improving two-phase circulation efficiency of the heat-conducting working medium.

The embodiments of the present disclosure are described in detail above with reference to the accompanying drawings, but the present disclosure is not limited to the foregoing embodiments, and various changes can be made within the knowledge scope of those having ordinary skills in the art without departing from the scope of the present disclosure. In addition, the embodiments of the present disclosure and the features in the embodiments can be mutually combined if not in collision.

1. A heat conducting plate, comprising: a heat conducting plate body, and a first heat dissipation zone, a second heat dissipation zone, and a third heat dissipation zone which are arranged on the heat conducting plate body, wherein:
the first heat dissipation zone is arranged adjacent to a first side of the heat conducting plate body, and the first side of the heat conducting plate body is configured as a heat input end;
the second heat dissipation zone is arranged adjacent to the first heat dissipation zone, and the second heat dissipation zone is provided with a second heat dissipation channel;
the third heat dissipation zone is arranged adjacent to the first heat dissipation zone and the second heat dissipation zone, and the third heat dissipation zone is provided with a third heat dissipation channel;
the second heat dissipation channel comprises at least a mesh-shaped channel;
the third heat dissipation channel comprises at least a strip-shaped channel; and
the second heat dissipation channel is communicated with the third heat dissipation channel.

2. The heat conducting plate of claim 1, wherein the heat conducting plate further comprises a heat-conducting working medium configured to flow in the second heat dissipation channel and the third heat dissipation channel, at least part of the heat-conducting working medium is configured to be liquefied in part of the second heat dissipation channel, and at least part of the liquefied heat-conducting working medium flows to the third heat dissipation channel through the second heat dissipation channel.

3. The heat conducting plate of claim 1, wherein the heat conducting plate further comprises a heat-conducting working medium, the first heat dissipation zone comprises a first heat dissipation channel, and the heat-conducting working medium is configured to flow to the first heat dissipation channel through the third heat dissipation channel.

4. The heat conducting plate of claim 3, wherein the heat conducting plate further comprises a heat-conducting working medium, at least part of the heat-conducting working medium is configured to be vaporized in part of the first heat dissipation channel, and at least part of the vaporized heat-conducting working medium flows to the second heat dissipation channel through the first heat dissipation channel.

5. The heat conducting plate of claim 1, wherein the second heat dissipation zone comprises a plurality of first closed units, the third heat dissipation zone comprises a plurality of second closed units, the first closed units are surrounded by at least part of the second heat dissipation channel, the second closed units are surrounded by at least part of the third heat dissipation channel, and the first closed units and the second closed units are configured as at least one of the following that:
the first closed units are first closed units comprising at least one shape or size;
the second closed units are second closed units comprising at least one shape or size;
at least some of the first closed units have a different shape from the second closed units; or
at least some of the first closed units have a different size from the second closed units.

6. The heat conducting plate of claim 1, wherein the strip-shaped channel comprises a plurality of guide pipes, and the plurality of guide pipes are spaced apart.

7. The heat conducting plate of claim 6, wherein the guide pipes are configured as at least one of the following that:
at least some of the guide pipes have one end communicated with the first heat dissipation zone and the other end communicated with the second heat dissipation zone;
at least two of the guide pipes have different lengths;
lengths of some of adjacent guide pipes increase gradually;
an end of the guide pipe close to the second heat dissipation zone has a greater diameter than an end of the guide pipe close to the first heat dissipation zone; and
an angle between the end close to the first heat dissipation zone and a first direction is less than 45 degrees.

8. The heat conducting plate of claim 6, wherein the third heat dissipation zone comprises a communicating pipe which connects at least two adjacent guide pipes.

9. The heat conducting plate claim 1, wherein a coupling zone is arranged between the second heat dissipation zone and the third heat dissipation zone, and the second heat dissipation channel and the third heat dissipation channel are communicated by means of the coupling zone.

10. A heat dissipation apparatus, comprising a heat conducting plate, the heat conducting plate comprising:
a heat conducting plate body, and a first heat dissipation zone, a second heat dissipation zone, and a third heat dissipation zone which are arranged on the heat conducting plate body, wherein:
the first heat dissipation zone is arranged adjacent to a first side of the heat conducting plate body, and the first side of the heat conducting plate body is configured as a heat input end;
the second heat dissipation zone is arranged adjacent to the first heat dissipation zone, and the second heat dissipation zone is provided with a second heat dissipation channel;
the third heat dissipation zone is arranged adjacent to the first heat dissipation zone and the second heat dissipation zone, and the third heat dissipation zone is provided with a third heat dissipation channel;
the second heat dissipation channel comprises at least a mesh-shaped channel;
the third heat dissipation channel comprises at least a strip-shaped channel; and
the second heat dissipation channel is communicated with the third heat dissipation channel.

11. The heat dissipation apparatus of claim 10, wherein the heat dissipation apparatus comprises a base configured as at least one of the following that:
an inner cavity of the base is communicated with the heat conducting plate, the heat conducting plate is provided with an open nozzle, and the inner cavity of the base is communicated with the heat conducting plate through the open nozzle; or
the inner cavity of the base is not communicated with the heat conducting plate, and the heat conducting plate has a closed nozzle.

12. An electronic device, comprising the heat conducting plate of claim 1.

13. The heat conducting plate of claim 2, wherein a coupling zone is arranged between the second heat dissipation zone and the third heat dissipation zone, and the second heat dissipation channel and the third heat dissipation channel are communicated by means of the coupling zone.

14. The heat conducting plate of claim 3, wherein a coupling zone is arranged between the second heat dissipation zone and the third heat dissipation zone, and the second heat dissipation channel and the third heat dissipation channel are communicated by means of the coupling zone.

15. The heat conducting plate of claim 4, wherein a coupling zone is arranged between the second heat dissipation zone and the third heat dissipation zone, and the second heat dissipation channel and the third heat dissipation channel are communicated by means of the coupling zone.

16. The heat conducting plate of claim 5, wherein a coupling zone is arranged between the second heat dissipation zone and the third heat dissipation zone, and the second heat dissipation channel and the third heat dissipation channel are communicated by means of the coupling zone.

17. The heat conducting plate of claim 6, wherein a coupling zone is arranged between the second heat dissipation zone and the third heat dissipation zone, and the second heat dissipation channel and the third heat dissipation channel are communicated by means of the coupling zone.

18. The heat conducting plate of claim 7, wherein a coupling zone is arranged between the second heat dissipation zone and the third heat dissipation zone, and the second heat dissipation channel and the third heat dissipation channel are communicated by means of the coupling zone.

19. The heat conducting plate of claim 8, wherein a coupling zone is arranged between the second heat dissipation zone and the third heat dissipation zone, and the second heat dissipation channel and the third heat dissipation channel are communicated by means of the coupling zone.

20. An electronic device, comprising the heat dissipation apparatus of claim 10.
